(19) United States
(12) Patent Application Publication
(10) Pub. No.: US 2002/0052116 A1
(43) Pub. Date: May 2, 2002

(54) Free Floating double side polishing of substrates

(76) Inventors: Krishna Vepa, Livermore, CA (US); Duncan Dobson, Woodside, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/812,242

(22) Filed: Mar. 19, 2001

Related U.S. Application Data
(60) Provisional application No. 60/190,278, filed on Mar. 17, 2000.
(60) Provisional application No. 60/190,463, filed on Mar. 17, 2000.

(51) Int. Cl. H01L 21/302; H01L 21/461; C23F 1/02

(52) U.S. Cl. 438/692; 156/345

(57) ABSTRACT

The present invention provides exemplary cluster tool systems and methods for processing wafers, such as semiconductor wafers, including exemplary double side polishing (DSP) systems and methods. One DSP system includes a first plate (710) having a first polishing surface and a second plate (712) having a second polishing surface. A translator for translating the first plate in a first direction and the second plate in a second direction is included. A carrier (718), adapted to receive a wafer (720) to be polished, is positioned between the first and second plates. The polishing apparatus includes a rotator (724) adapted to rotate the wafer between the first and second polishing surfaces. In this manner, polishing action occurs from the combination of wafer rotation, first plate translation and second plate translation. Further, the apparatus has a small footprint.

### CROSS-REFERENCES TO RELATED APPLICATIONS

This application claims the benefit of the following U.S. Patent Applications, the complete disclosures of which are incorporated herein by reference:

Provisional Application No. 60/190,278 (Attorney Docket No. 20648-000100), filed on Mar. 17, 2000;

Provisional Application No. 60/190,463 (Attorney Docket No. 0468-000400), filed on Mar. 17, 2000; and

U.S. patent application Ser. No. (Attorney Docket No. ______ (Attorney Docket No. 20468-000110), entitled “Cluster Tool Systems and Methods for Processing Wafers,” filed on Mar. 15, 2001.

### BACKGROUND OF THE INVENTION

The present invention is directed to the processing of wafers, substrates or disks, such as silicon wafers, and more specifically to cluster tool systems and methods for processing wafers prior to device formation.

Wafers or substrates with exemplary characteristics must first be formed prior to the formation of circuit devices. In determining the quality of the semiconductor wafer, the flatness of the wafer is a critical parameter to customers since wafer flatness has a direct impact on the subsequent use and quality of semiconductor chips diced from the wafer. Hence, it is desirable to produce wafers having as near a planar surface as possible.

In a current practice, cylindrical boules of single-crystal silicon are formed, such as by Czochralski (CZ) growth process. The boules typically range from 100 to 300 millimeters in diameter. These boules are cut with an internal diameter (ID) saw or a wire saw into disc-shaped wafers approximately one millimeter (mm) thick. The wire saw reduces the kerf loss and permits many wafers to be cut simultaneously. However, the use of these saws results in undesirable waviness of the surfaces of the wafer. For example, the topography of the front surface of a wafer may vary by as much as 1-2 microns (μ) as a result of the natural distortions or warpage of the wafer as well as the variations in the thickness of the wafer across its surface. It is not unusual for the amplitude of the waves in each surface of a wafer to exceed fifteen (15) micrometers. The surfaces need to be made more planar (planarized) before they can be polished, coated or subjected to other processes.

FIG. 1 depicts a typical prior art method 10 for processing a silicon wafer prior to device formation. Method 10 includes a slice step 12 as previously described to remove a disc-shaped portion of wafer from the silicon boule. Once the wafer has been sliced, the wafer is cleaned and inspected (Step 14). Thereafter, an edge profile process (Step 16) is performed. Once the edge profile has been performed, the wafer is again cleaned and inspected (Step 18), and is laser marked (Step 20).

Next, a lapping process (Step 22) is performed to control thickness and remove bow and warp of the silicon wafer. The wafer is simultaneously lapped on both sides with an abrasive slurry in a lapping machine. The lapping process may involve one or more lapping steps with increasingly finer polishing grit. The wafer is then cleaned (Step 24) and etched (Step 26) to remove damage caused by the lapping process. The etching process may involve placing the wafer in an acid bath to remove the outer surface layer of the wafer. Typically, the etchant is a material requiring special handling and disposal. Thereafter, an additional cleaning of the wafer (Step 28) is performed.

The prior art method continues with a donor anneal (Step 30) followed by wafer inspection (Step 32). Thereafter, the wafer edge is polished (Step 24) and the wafer is again cleaned (Step 36). Typical wafer processing involves the parallel processing of a multitude of wafers. Hence at this juncture wafers may be sorted, such as by thickness (Step 38), after which a double side polish process is performed (Step 40).

The wafers then are cleaned (Step 42) and a final polish (Step 44) is performed. The wafers are again cleaned (Step 46), inspected (Step 48) and potentially cleaned and inspected again (Steps 50 and 52). For epitaxial substrates, a poly or oxide layer is overlaid to seal in the dopants after inspection Step 52. At this point, the wafer is packed (Step 54), shipped (Step 56) and delivered to the end user (Step 58). Hence, as seen in FIG. 1 and as described above, typical wafer processing involves a lengthy, time consuming process with a large number of processing steps.

A number of deficiencies exist with the prior art method. As can be seen from even a precursory review of FIG. 1, the prior art method requires a large number of steps to transform a wafer slice into a substrate suitable for creating circuit devices. The large number of process steps involved negatively effects production throughput, requires a large production area, and results in high fabrication costs. Additionally, each of the steps in FIG. 1 are typically performed at individual process stations. The stations are not grouped or clustered together, and manual delivery of the wafers between stations is often used.

In addition to the large number of process steps, at least some of the prior art steps themselves are slow or produce unacceptable results. For example, polishing Step 40 typically involves simultaneously polishing a large number of wafers (e.g., ten (10) or more) on a huge polisher spanning ten (10) to fifteen (15) feet a side. Polishing such a large number of wafers makes it extremely difficult to track which wafer is which after the up to hundreds or more rotations of the wafers about the polishing table. Further, the wafers are typically loaded and unloaded by hand, a time consuming process subject to human error and wafer damage. These additional steps cause the conventional method to be more expensive and time-consuming than methods of the present invention. Also, the etching process employed after the lapping step is undesirable from an environmental standpoint, because the large amount of strong acids used must be disposed of in an acceptable way.

In another prior art method, a grinding process replaces the lapping procedure in FIG. 1. A first surface of the wafer is drawn or pushed against a hard flat holder while the second surface of the wafer is ground flat. The forces used to hold the wafer elastically deform the wafer during grinding of the second surface. When the wafer is released, elastic restoring forces in the wafer cause it to resume its original shape, and it can be seen that the waves in the first surface have been transferred to the surface that has been ground. Thus while this technique produces a wafer of more uniform thickness, it does not eliminate the residual saw waves.

Additional deficiencies in the current art, and improvements in the present invention, are described below and will be recognized by those skilled in the art.

### SUMMARY OF THE INVENTION

The present invention provides exemplary cluster tool systems and methods for processing wafers, such as semiconductor wafers, including systems and methods for double side polishing.

In one embodiment of the present invention, an apparatus for polishing a substrate includes a first plate having a first polishing surface and a second plate having a second polishing surface. A translator for translating the first plate in a first direction and the second plate in a second direction is provided. The apparatus includes a carrier adapted to receive a wafer to be polished, with the carrier positioned between the first and second plates. The polishing apparatus includes a rotator adapted to rotate the wafer between the first and second polishing surfaces. In this manner, polishing action occurs from the combination of wafer rotation, first plate translation and second plate translation.

In one aspect, the first and second polishing surfaces include polishing pads. In a particular aspect, the first direction is generally perpendicular to the second direction. In one aspect, the carrier is adapted to receive at least three wafers.

In another aspect, the carrier further includes a unique identification mark positioned adjacent the wafer. In one embodiment the apparatus includes a detection device for reading the identification mark to locate a wafer position. Preferably, the wafer carrier includes a non-metallic material, and has a thickness that is less than a thickness of the wafer. In this manner, the carrier does not impart damage to the peripheral edge of the wafer due to its non-metallic materials. Additionally, the wafer extends out of the carrier in a manner permitting its contact with the polishing surfaces.

In one aspect, the polishing apparatus includes a carrier ring coupled to a periphery of the carrier. In one embodiment, the rotator is adapted to rotate the carrier by engaging the carrier ring. In one aspect, the polishing apparatus further includes a controller coupled to the rotator and translator. In this manner, rotation and translation may be controlled and coordinated by the controller. Further, more than one translator may be used.

In one aspect, the polishing apparatus of the present invention has a footprint that is less than about 20 square feet. In this manner, the footprint is considerably smaller than prior art polishers and facilitates its incorporation into the cluster tool concept of the present invention. Preferably, the polishing surfaces are generally parallel to one another, and such positioning may be accomplished by a gimballing device coupled to one or both plates. In one aspect, the second plate further includes a plurality of spaced apart holes coupled to a fluid source. This fluid source may include a slurry, deionized water and the like.

The present invention further provides methods for polishing a wafer. In one embodiment, the method includes placing a wafer in a carrier, with the carrier having an identification mark adjacent the wafer to identify a wafer position. The method includes positioning the wafer between first and second polishing plates, and translating the first plate in a first direction while simultaneously translating the second plate in a second direction different than the first direction. In one embodiment, the translating comprises a back and forth or side to side motion. The method includes rotating the carrier to rotate the wafer relative to the first and second polishing plates. The method further includes positioning the first and second plates to contact first and second surfaces of the wafer during rotation of the carrier in order to polish the first and second surfaces.

In one aspect, translating the first plate is 90 degrees to 180 degrees out of phase with translating the second plate, and in another aspect the first and second directions of translation are generally perpendicular to one another. In one aspect the method further includes removing the wafer from the carrier after the polishing, wherein the removing process includes impinging a wafer surface with a series of fluid jets to at least partially lift the wafer from the carrier.

Other objects, features and advantages of the present invention will become more fully apparent from the following detailed description, the appended claims and the accompanying drawings.

### BRIEF DESCRIPTION OF THE DRAWINGS

FIG. 1 depicts a prior art method for processing a silicon wafer;

FIG. 2 is a simplified flow diagram of a wafer processing method according to the present invention;

FIGS. 3A-C depict grind damage cluster tools according to the present invention;

FIG. 4 depicts an edge profile/polish cluster tool according to the present invention;

FIGS. 5A and 5B depict double side polish cluster tools according to the present invention;

FIG. 6 depicts a finish polish cluster tool according to the present invention;

FIG. 7A is a simplified schematic of a double side polisher for use in the cluster tools shown in FIGS. 5A and 5B;

FIG. 7B is a simplified top view of a substrate carrier for use in the double side polisher of FIG. 7A; and

FIGS. 8A-8C are graphical representations of test data of 219 wafers polished on apparatus, and according to methods, of the present invention.

### DESCRIPTION OF THE SPECIFIC EMBODIMENTS

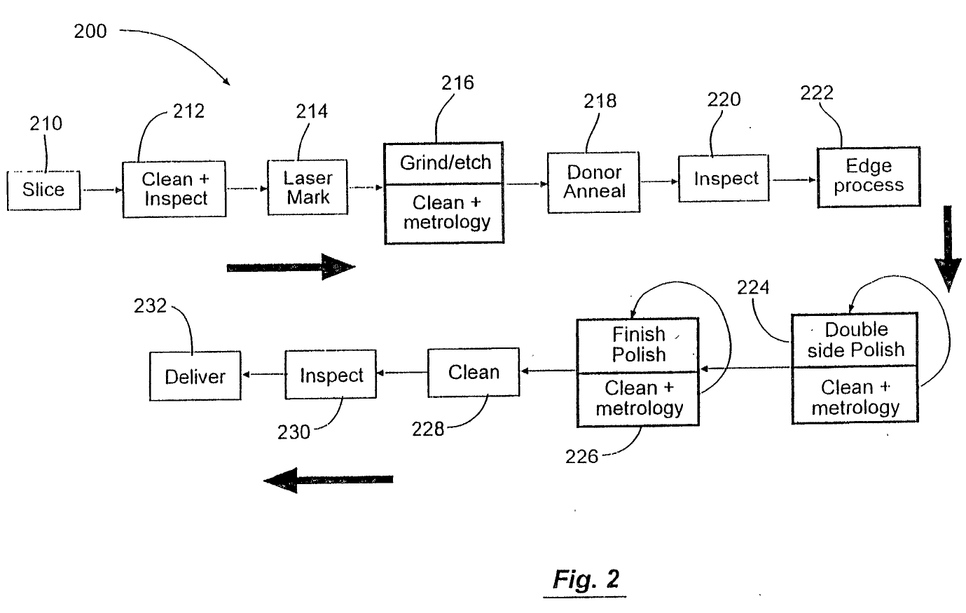

FIG. 2 depicts an exemplary method 200 of the present invention. Method 200 includes a slice process 210, using a wire saw, inner diameter saw or the like, to create a generally disc-shaped wafer or substrate. In one embodiment, the wafer is a silicon wafer. Alternatively, the wafer may comprise polysilicon, germanium, glass, quartz, or other materials. Further, the wafer may have an initial diameter of about 200 mm, about 300 mm, or other sizes, including diameters larger than 300 mm.

The wafer is cleaned and inspected (Step 212) and then may, or may not, be laser-marked (Step 214). Laser marking involves creating an alphanumeric identification mark on the wafer. The ID mark may identify the wafer manufacturer, flatness, conductivity type, wafer number and the like. The laser marking preferably is performed to a sufficient depth so that the ID mark remains even after portions of the wafer have been removed by subsequent process steps such as grinding, etching, polishing, and the like.

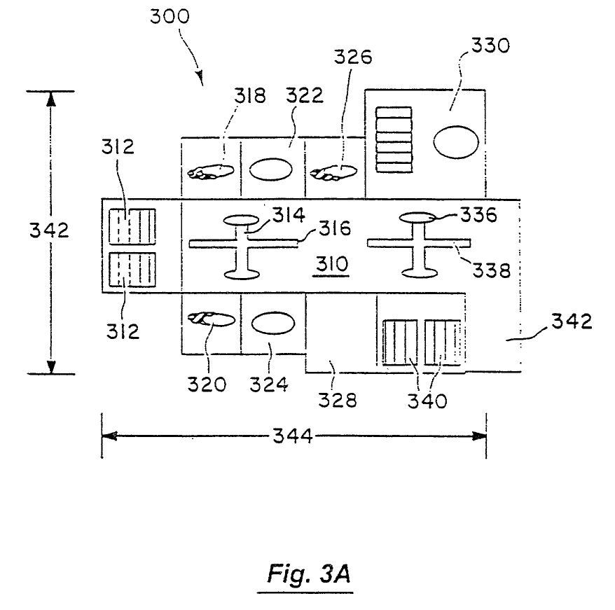

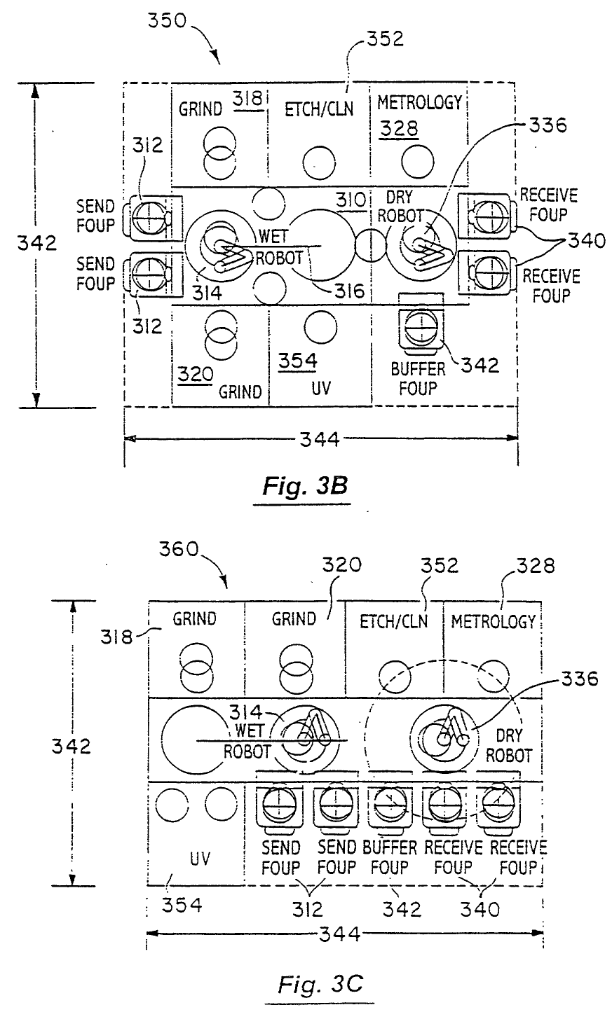

Thereafter, the wafer is processed through a first module (Step 216), with details of embodiments of the first module described below in conjunction with FIGS. 3A-3C. First module processing (Step 216) includes a grinding process, an etching process, a cleaning process and metrology testing of the wafer. In this module, the use of a grinding process in lieu of lapping helps to remove wafer bow and warpage. The grinding process of the present invention also is beneficial in removing wafer surface waves caused by the wafer slicing in Step 210. Benefits of grinding in lieu of lapping include reduced kerf loss, better thickness tolerance, improved wafer shape for polishing and better laser mark dot depth tolerance, and reduced damage, among others.

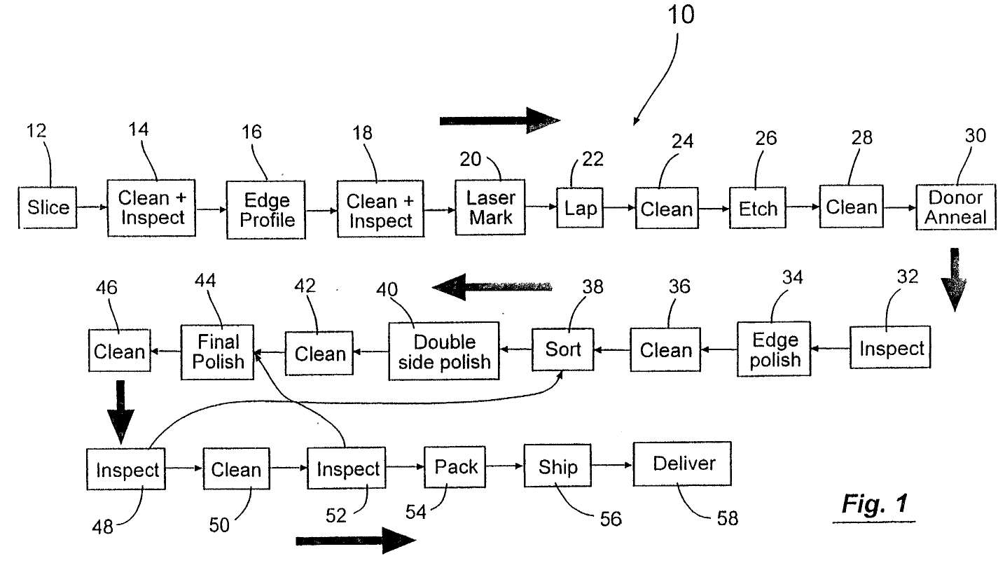

The etching process within the first module is a more benign process than the prior art etch step described in conjunction with FIG. 1. For example, typical prior art etching (Step 26 in FIG. 1) may involve the bulk removal of forty (40) or more microns of wafer thickness. In contrast, the etch process of the present invention preferably removes ten (10) microns or less from the wafer thickness. In one embodiment, the first module etch process removes between about two (2) microns to about five (5) microns of wafer material per side, or a total of about four (4) to about ten (10) microns. In another embodiment, the first module etch process removes between about three (3) microns and about four (4) microns of wafer material per side for a total of about six (6) to about (8) microns.

After first module processing, the wafer is subjected to a donor anneal (Step 218) and thereafter inspected (Step 220). The donor anneal removes unstable oxygen impurities within the wafer. As a result, the original wafer resistivity may be fixed. In an alternative embodiment, donor anneal is not performed.

The wafer then is processed through a second module (Step 222) in which an edge process is performed. The edge process includes both an edge profile and an edge polish procedure. Edge profiling may include removing chips from the wafer edge, controlling the diameter of the wafer and/or the creation of a beveled edge. Edge profiling also may involve notching the wafer to create primary and secondary flat edges. The flats facilitate wafer alignment in subsequent processing steps and/or provide desired wafer information (e.g., conductivity type). In one embodiment, one or both flats are formed near the ID mark previously created in the wafer surface. One advantage of the present invention involves performing the edge profiling after wafer grinding. In this manner, chips or other defects to the wafer edge, which may arise during grinding or lapping, are more likely to be removed. Prior art edge profiling occurs before lapping, and edge polishing subsequent to the lapping step may not sufficiently remove edge defects.

The wafer is then processed through a third module (Step 224). A third module process includes a double side polish, a cleaning process and wafer metrology. Wafer polishing is designed to remove stress within the wafer and smooth any remaining roughness. The polishing also helps eliminate haze and light point defects (LPD) within the wafer, and produces a flatter, smoother finish wafer. As shown by the arrow in FIG. 2, wafer metrology may be used to adjust the double side polishing process within the third module. In other words, wafer metrology may be feed back to the double side polisher and used to adjust the DSP device in the event the processed wafer needs to have different or improved characteristics, such as flatness, or to further polish out scratches.

Thereafter, the wafer is subjected to a finish polish, a cleaning process and metrology testing, all within a fourth process module (226). The wafer is cleaned (Step 228), inspected (Step 230) and delivered (Step 232).

The reduced number of clean and inspection steps, particularly near the end of the process flow, are due in part to the exemplary metrology processing of the wafer during prior process steps. Wafer metrology testing may test a number of wafer characteristics, including wafer flatness, haze, LPD, scratches and the like. Wafer flatness may be determined by a number of measuring methods known to those skilled in the art. For example, “taper” is a measurement of the lack of parallelism between the unpolished back surface and a selected focal plane of the wafer. Site Total Indicated Reading (STIR) is the difference between the highest point above the selected focal plane and the lowest point below the focal plane for a selected portion (e.g., 1 square cm) of the wafer, and is always a positive number. Site Focal Plane Deviation (SFPD) is the highest point above, or the lowest point below, the chosen focal plane for a selected portion (e.g., 1 square cm) of the wafer and may be a positive or negative number. Total thickness variation (TTV) is the difference between the highest and lowest elevation of the polished front surface of the wafer.

Further, metrology information, in one embodiment, is fed back and used to modify process parameters. For example, in one embodiment metrology testing in the first module occurs after wafer grinding and may be used to modify the grinding process for subsequent wafers. In one embodiment, wafers are processed through the first module in series. More specifically, each station within the first module processes a single wafer at a time. In this manner, metrology information may be fed back to improve the grinding or other process after only about one (1) to five (5) wafers have been processed. As a result, a potential problem can be corrected before a larger number of wafers have been processed through the problem area, thus lowering costs.

Further, the present invention produces standard process times for each wafer. More specifically, each wafer is subjected to approximately the same duration of grinding, cleaning, etching, etc. The delay between each process also is the same or nearly the same for each wafer. As a result, it is easy to troubleshoot within the present invention methods and systems.

In contrast, prior art methods typically uses a batch process mode for a number of process steps. For example, a batch containing a large number of wafers (say, twenty (20)) may be lapped one to a few at a time (say, one (1) to four (4) at a time). After all twenty have been lapped, the batch of twenty wafers then are cleaned together as a group (Step 24), and etched together as a group (Step 26). As a result, the wafers that were lapped first sit around for a longer period of time prior to cleaning than do the wafers lapped last. This varying delay effects wafer quality, due in part to the formation of a greater amount of haze, light point defects, and other time-dependent wafer defects. One negative outcome of irregular process times is the resultant difficulty in locating potential problems within the process system.

As with the first module, metrology information may be fed back within the second, third and fourth modules. For example, metrology information may be fed back to the double side polisher or finish polisher to adjust those processes to produce improved results. Additionally, in one embodiment, metrology information is fed back within the third and/or fourth module in real time. As a result, process steps such as the double side polishing can be modified during processing of the same wafer on which metrology testing has occurred.

With reference to FIGS. 3-6, additional details on process modules according to the present invention will be provided. It will be appreciated by those skilled in the art that the process modules described in FIGS. 3-6 are embodiments of the present invention, from which a large number of variations for each module exist within the scope of the present invention. Further, additional process steps may be removed or added, and process steps may be rearranged within the scope of the present invention.

FIG. 3A depicts a grind damage cluster module described as first module 216 in conjunction with FIG. 2. First module 300 defines a clean room environment 310 in which a series of process steps are carried out. Wafers that have been processed through Step 214 (FIG. 2) are received in first module 300 via a portal, such as a front opening unified pod (FOUP) 312. First module 300 is shown with two FOUPs 312, although a larger or smaller number of FOUPs/portals may be used. FOUPs 312 are adapted to hold a number of wafers so that the frequency of ingress into the clean room environment 310 may be minimized. A transfer device 314, schematically depicted as a robot, operates to remove a wafer from FOUPs 312 and place the wafer on a grinder 318. If needed, transfer device 314 travels down a track 316 to properly align itself, and hence the wafer, in front of grinder 318. Grinder 318 operates to grind a first side of the wafer.

The wafer may be held down on grinder 318 by way of a vacuum chuck, and other methods. Once grinder 318 has ground the first side of the wafer, the wafer is cleaned in cleaner 322 and the transfer device 314 transfers the wafer back to grinder 318 for grinding the converse side of the wafer. In one embodiment, wafer grinding of both wafer sides removes about forty (40) microns to about seventy (70) microns of wafer thickness. After the second wafer side is ground, the wafer is again cleaned in cleaner 322. In one embodiment, cleaning steps occur on grinder 318 subsequent to grinding thereon. In one embodiment, cleaning and drying are accomplished by spraying a cleaning solution on the wafer held by or near the edges and spun.

In another embodiment, at least one side of the wafer is subjected to two sequential grinding steps on grinder 318. The two grinding processes preferably include a coarse grind followed by a fine grind. Grinder 318 may include, for example, two different grinding platens or pads with different grit patterns or surface roughness. In one embodiment, the wafer is cleaned on grinder 318 between the two grinding steps to the same wafer side. Alternatively, cleaning may occur after both grinding steps to the same wafer side.

In some embodiments, transfer device 314 transfers the wafer from cleaner 322 to a backside polisher 326. For example, this process flow may occur for 200 mm wafers. In this embodiment, the back side is polished and not ground, or both ground and polished.

As shown in FIG. 3A, a second grinder 320 and a second cleaner 324 are provided within module 300. In this manner, two wafers may be simultaneously processed therethrough. Since both grinders 318, 320 have a corresponding cleaner 322, 324, wafer processing times are consistent even if two wafers are being ground simultaneously on grinders 318, 320. In one embodiment, grinders 318 and 320 are used to grind opposite sides of the same wafer. In this case, one side of the wafer is ground on grinder 318 and the other side of the same wafer is ground on grinder 320. As with grinder 318, wafers may be ground on grinder 320 and then cleaned on grinder 320 before removal, or cleaned in cleaner 324.

Once the wafers have been ground, a second transfer device 336, again a robot in one embodiment, operates to transfer the wafer to an etcher 330. Etcher 330 operates to remove material from the wafer, preferably a portion on both primary sides of the wafer. The etching process is designed to remove stresses within the silicon crystal caused by the grinding process. Such an operation, in one embodiment, removes ten (10) microns or less of total wafer thickness. In this manner, etcher 330 operates to remove less wafer material than in prior art etch processes. Further, the present invention requires less etchant solution, and hence poses fewer environmental problems related to disposal of the acids or other etchants.

Wafer metrology is then tested at a metrology station 328. In one embodiment wafer metrology is tested subsequent to grinding on grinder 318, and prior to the etching within etcher 330. Alternatively, wafer metrology is tested subsequent to etching in etcher 330. In still another embodiment, wafer metrology is tested both prior to and subsequent to the etching process. Evaluation of wafer metrology involves the testing of wafer flatness and other wafer characteristics to ensure the wafer conforms to the desired specifications. If the wafer does not meet specifications, the wafer is placed in a recycle area 342, which in one embodiment comprises a FOUP 342 (not shown in FIG. 3A). Wafers with acceptable specifications are placed in an out portal or FOUP 340 for removal from first module 300.

As shown and described in conjunction with FIG. 3A, first module 300 provides an enclosed clean room environment in which a series of process steps are performed. Wafers are processed in series through first module 300. Hence, each wafer has generally uniform or uniform process time through the module as well as generally uniform or uniform delay times between process steps. Further, by immediately cleaning and etching the wafer after grinding, the formation of haze and light point defects (LPD) within the wafer are reduced. Such a module configuration is an improvement over the prior art in which wafers are typically processed during the lapping step in batch mode. As a result, some wafers will wait longer before the cleaning or etching steps than others within the same batch. As a result, haze and other wafer defects vary from wafer to wafer, even between wafers within the same batch. Such a shortcoming of the prior art can make it difficult if not impossible to isolate problems within the wafer process flow in the event defective wafers are discovered.

An additional benefit of first module 300 is its compact size. In one embodiment, module 300 has a width 342 that is about 9 feet 3 inches and a length 344 that is about 12 feet 6 inches. In another embodiment, first module 300 has a footprint ranging between about ninety (90) square feet (sqft) and about one hundred and fifty (150) square feet. It will be appreciated by those skilled in the art that the width and length, and hence the footprint of first module 300, may vary within the scope of the present invention. For example, additional grinders 318, 320 may be added within first module 300 to increase the footprint of module 300. In one embodiment, first module 300 is adapted to process about thirty (30) wafers per hour. In another embodiment, first module 300 is adapted to process between about twenty-nine (29) and about thirty-three (33) 300 mm wafers per hour.

FIG. 3B depicts an alternative embodiment of a grind damage cluster module according to the present invention. Again, the grind damage cluster module 350 may correspond to first module 216 described in conjunction with FIG. 2. Module 350 includes many of the same components as the embodiment depicted in FIG. 3A, and like reference numerals are used to identify like components. Module 350 receives wafers or substrates to be processed at portal 312, identified as a send FOUP 312 in FIG. 3B. Wafers are transferred by transfer device 314, shown as wet robot 314, to a preprocessing station 354. In one embodiment, transfer device 314 travels on a track, groove, raised member or other mechanism which allows transfer device 314 to reach several process stations within module 350.

At preprocessing station 354, a coating is applied to one side of the wafer. In one embodiment, a polymer coating is spun on the wafer to provide exemplary coverage. This coating then is cured using ultraviolet (UV) light to provide a low shrink, rapid cured coating on one side of the wafer. In addition to UV curing, curing of the coating may be accomplished by heating and the like. In a particular embodiment, the coating is applied to a thickness between about five (5) microns and about thirty (30) microns.

Once cured, the coating provides a completely or substantially tack free, stress free surface on one side of the wafer. In one embodiment of the present invention, transfer device 314 transfers the wafer to grinder 318, placing the polymer-coated side down on the grinder 318 platen. In one embodiment, the platen is a porous ceramic chuck which uses a vacuum to hold the wafer in place during grinding. The waves created during wafer slicing are absorbed by the coating and not reflected to the front side of the wafer when held down during the grinding process. After the first wafer side is ground on grinder 318, the wafer is flipped over and the second side is ground. As described in conjunction with FIG. 3A, an in situ clean of the wafer may occur before turning the wafer, or the wafer may be cleaned subsequent to grinding of both sides. Again, the second side grinding may occur on grinder 318 or grinder 320. Grinding of the second side removes the cured polymer, and a portion of the second wafer surface resulting in a generally smooth wafer on both sides, with little to no residual surface waves. Additional details on exemplary grinding methods are discussed in U.S. patent application Ser. No. ______ (Attorney Docket No. 20468-001010), filed contemporaneously herewith, the complete disclosure of which is incorporated herein by reference.

After grinding on grinder 318 and/or 320, the wafer is transferred to a combined etch/clean station 352 for wafer etch. Again, wafer etching in station 352 removes a smaller amount of wafer material, and hence requires a smaller amount of etchant solutions, than is typically required by prior art processes.

Processing continues through module 350 ostensibly as described in FIG. 3A. The wafer metrology is tested at metrology station 328. Wafers having desired characteristics are transferred by transfer device 336, shown as a dry robot, to out portals 340, identified as receive FOUPS 340 in FIG. 3B. Wafers having some shortcoming or undesirable parameter are placed in a recycle area 342, shown as a buffer FOUP 342, for appropriate disposal.

In one embodiment, module 350 has a width 342 at its widest point of about one hundred and fourteen (114) inches, and a length at its longest point of about one hundred and forty-five inches (145), with a total footprint of about one hundred and fourteen square feet (114 sqft). As will be appreciated by those skilled in the art, the dimensions and footprint of module 350 may vary within the scope of the present invention.

Still another embodiment of a grind damage cluster module according to the present invention is shown in FIG. 3C. FIG. 3C depicts a first module 360 having similar stations and components as module 350 described in FIG. 3B. However, module 350 is a flow through module, with wafers being received at one end or side of module 350 and exiting an opposite end or side of module 350. Module 360 has FOUPS 312, 342 and 340 grouped together. Such a configuration provides a single entry point into module 360, and hence into clean room environment 310. Transfer devices 314 and 336 again facilitate the movement of wafers from station to station within module 360. As shown in FIGS. 3B and 3C, transfer device 314 travels on mechanism 316, as discussed in conjunction with FIG. 3B. Transfer device 336 operates from a generally fixed position with arms or platens extending therefrom to translate the wafer to the desired processing station. Module 360 further includes station 354 for application of a wafer coating, such as the UV cured polymer coating described above.

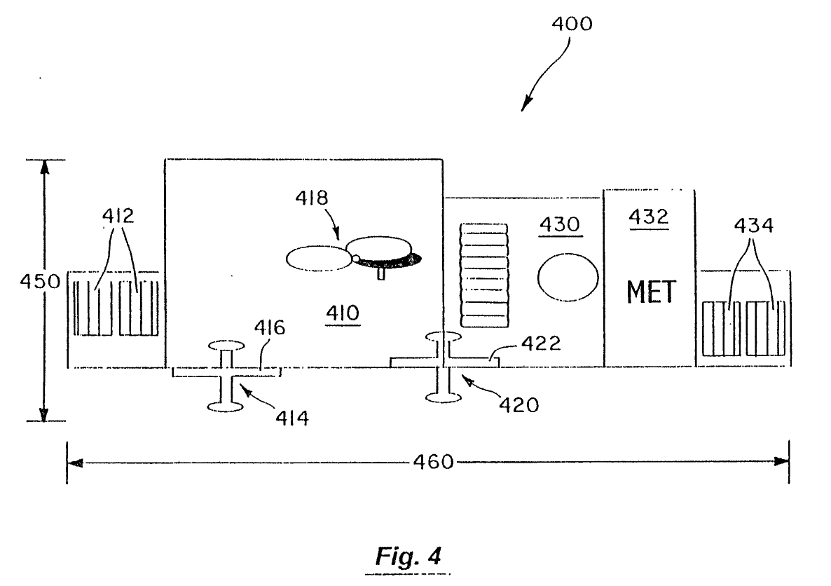

Turning now to FIG. 4, an exemplary second module comprising an edge profile and edge polishing module will be described. Second module 400 again includes a clean room environment 410 to facilitate clean operations. Second module 400 has a portal 412 for receiving wafers to be processed. Again, in one embodiment, portal 412 is one or more FOUPs. A robot or other transfer device 414 operates to take a wafer from portal 412 and transfer the wafer to an edge profiler/polisher 418. Edge profiler/polisher 418 may comprise one device, or two separate devices with the first device for profiling and the second device for polishing. Transfer device 414 may travel down a track 416 to permit proper placement of the wafer in the edge profiler/polisher 418.

The edge of the wafer is profiled and polished as described in conjunction with FIG. 2. In one embodiment, edge profiling removes about ten (10) microns to about fifty (50) microns of material from the diameter of the wafer, with a resultant diameter tolerance of about +/−0.5μ. After edge profiling and polishing, a transfer device 420 operates to transfer the wafer to a cleaner 430. Again, transfer device 420 may travel on a track 422 to place the wafer in cleaner 430. Cleaner 430 may comprise a mixture of dilute ammonia, peroxide, and water, or an ammonia peroxide solution and soap, followed by an aqueous clean, and the like.

Subsequent to cleaning in cleaner 430, the wafer is transferred to a metrology station 432 at which wafer metrology is examined. An out-portal 434 is positioned to receive wafers having successfully completed processing through second module 400. In one embodiment, portal 434 is a FOUP which collects wafers meeting desired specifications. Again, rejected wafers are set aside in a separate area or FOUP.

Second module 400 has a compact configuration similar to first module. In one embodiment, second module 400 has a width 450 of about 7 feet 6 inches and a length 460 of about 22 feet 11 inches. In another embodiment, second module 400 has a footprint ranging between about ninety (90) square feet (sqft) and about one hundred and fifty (150) square feet. The module 400 shown in FIG. 4 may be used to carry out process step 222 depicted in FIG. 2. In one embodiment, second module 400 processes about thirty (30) wafers per hour. In another embodiment, second module 400 is adapted to process between about twenty-nine (29) and about thirty-three (33) 300 mm wafers per hour. In still another embodiment, second module 400 processing occurs prior to first module 300 processing. In this manner, edge profile and/or edge polish procedures occur before wafer grinding.

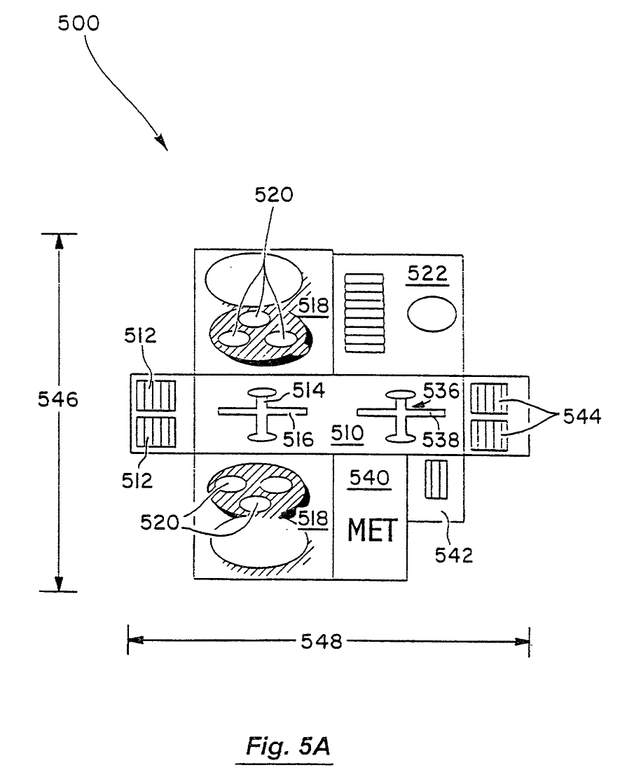

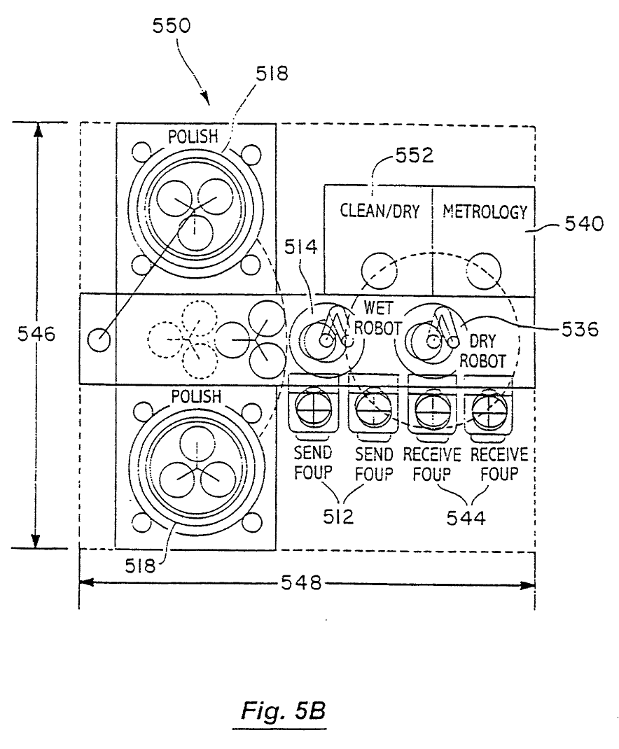

FIG. 5A depicts a third module 500 comprising a double side polisher for use in process step 224 shown in FIG. 2. Module 500 again includes an in-portal 512 which may be one or more FOUPs in one embodiment. Wafers are received in portal 512 and transferred within a clean room environment 510 by a transfer device 514. Transfer device 514, which in one embodiment is a robot, may travel along a track 516 to deliver the wafer to one or more double side polishers (DSP) 518.

As shown in FIG. 5A, double side polisher 518 accommodates three wafers 520 within each polisher. It will be appreciated by those skilled in the art that a greater or fewer number of wafers may be simultaneously polished within DSP 518. Prior art double side polishing (DSP) typically polishes a batch of ten or more wafers at a time in a double side polisher. The polisher initially only contacts the two or three thickest wafers due to their increased height within the DSP machine. Only after the upper layers of the thickest wafers are removed by polishing, are additional wafers polished within the batch. As a result, the batch mode polishing takes longer, and uses more polishing fluids and deionized water than in the present invention.

Hence in one preferred embodiment of the present invention, three wafers are polished simultaneously. Subsequent to polishing on polisher 518, the wafers are transferred via a transfer device 536, traveling on track 538 to a buffer station 522. Thereafter, the wafers are buffed, cleaned and dried. Either prior to or after processing through station 522, or both, wafers are tested at a metrology station 540. For wafers meeting desired specifications, transfer device 536 transfers those wafers to an out-portal 544, again, one or more FOUPs in one embodiment. Wafers which do not meet specifications are placed in a reject FOUP 542.

As with prior modules, the third module 500 has a compact footprint. In one embodiment, module 500 has a width 546 that is about 13 feet 11 inches and a length 548 that is about 15 feet 11 inches. In another embodiment, third module 500 has a footprint ranging between about one hundred (100) square feet (sqft) and about one hundred and eighty (180) square feet. Third module 500 may have a different footprint within the scope of the present invention.

In one embodiment, DSP 518 removes about twelve (12) microns of wafer thickness from both sides combined, at a rate of about 1.25 to 2.0 microns per minute. DSP 518 operates on a twelve (12) minute cycle time per load. Hence, in one embodiment, two DSPs 518 process about thirty (30) wafers per hour. In another embodiment, third module 500 is adapted to process between about twenty-nine (29) and about thirty-three (33) 300 mm wafers per hour. It will be appreciated by those skilled in the art that DSP 518 process times, third module 500 throughput, and other parameters may vary within the scope of the present invention. For example, additional DSPs 518 may be added to increase module 500 throughput. In one embodiment, wafer metrology tested at metrology station 540 is fed back to DSPs 518 to adjust DSP 518 operation as needed to produce desired wafer metrology.

FIG. 5B depicts an alternative embodiment of a third module according to the present invention. As shown in FIG. 5B, third module 550 comprises a double side polisher for use in process step 224 shown in FIG. 2, as well as several other components shown in FIG. 5A. As a result, like components are identified with like reference numerals. Module 550 includes a clean/dry station 552 for wafer cleaning and drying subsequent to wafer polishing in polisher 518. Transfer devices 514 and 536, shown as a wet robot and a dry robot, respectively, operate to transfer wafers within module 550. In one embodiment, transfer device 514 travels on a track, groove, raised feature or the like to reach several processing stations and portals 512, while transfer device 536 operates from a fixed base.

While module 500 in FIG. 5A is a flow through module, with wafers received by module 500 at one side and exiting from an opposite side, module 550 in FIG. 5B groups portals 512 and 544. Again, such a grouping of in and out portals facilitates access to module 550 from a single point or side. In one embodiment, a buffer or reject FOUPS (not shown) also is grouped with portals 512 and 544. Alternatively, one or more of portals 512 and 544 may operate as a reject FOUPS.

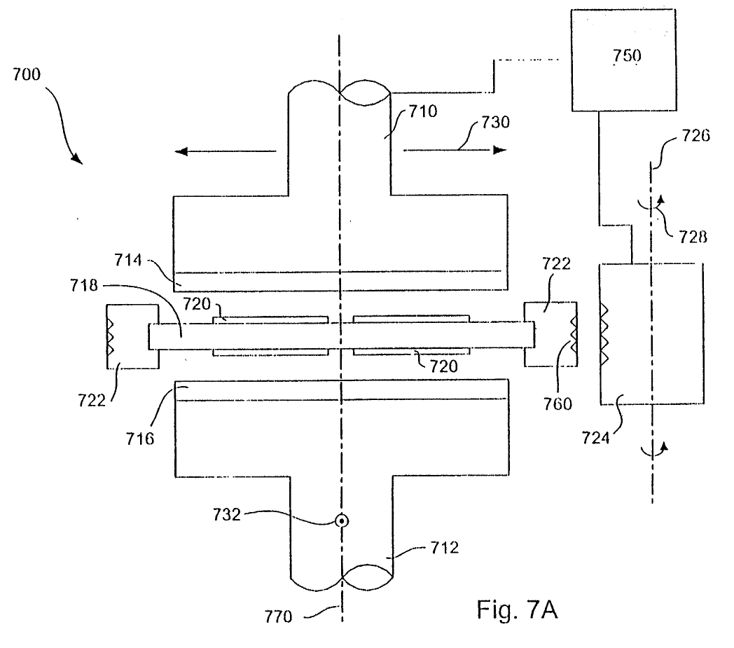

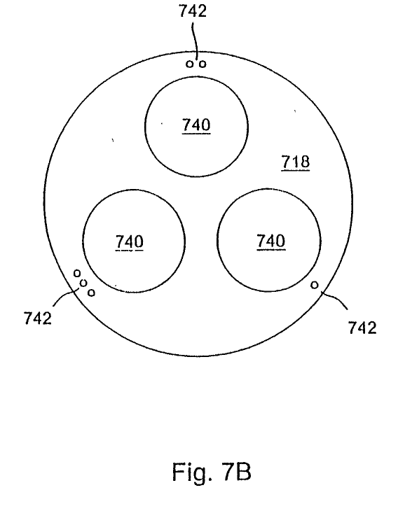

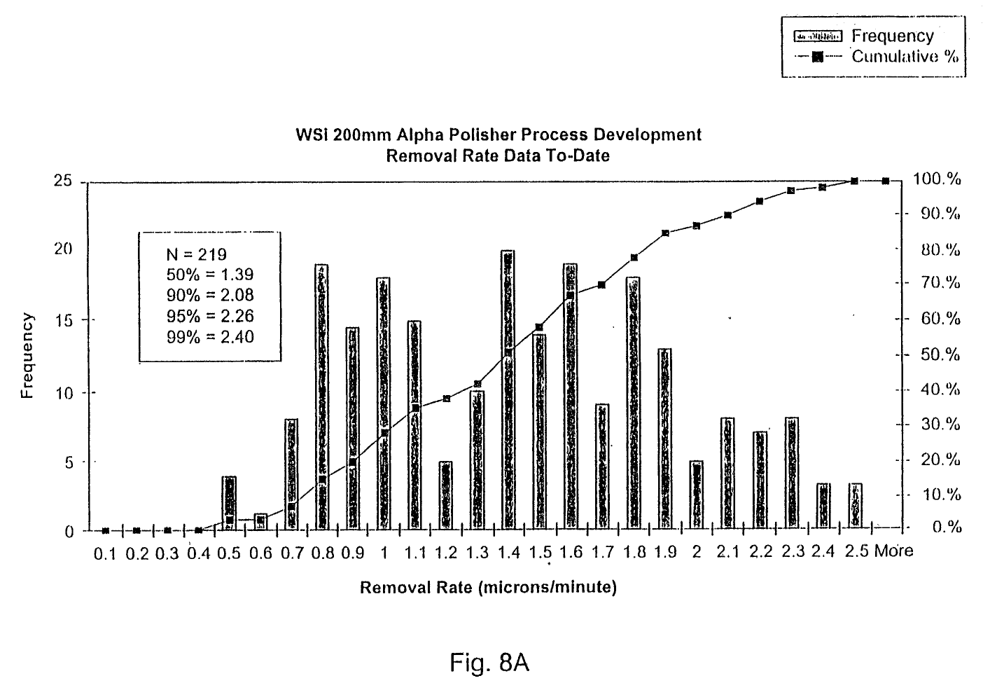

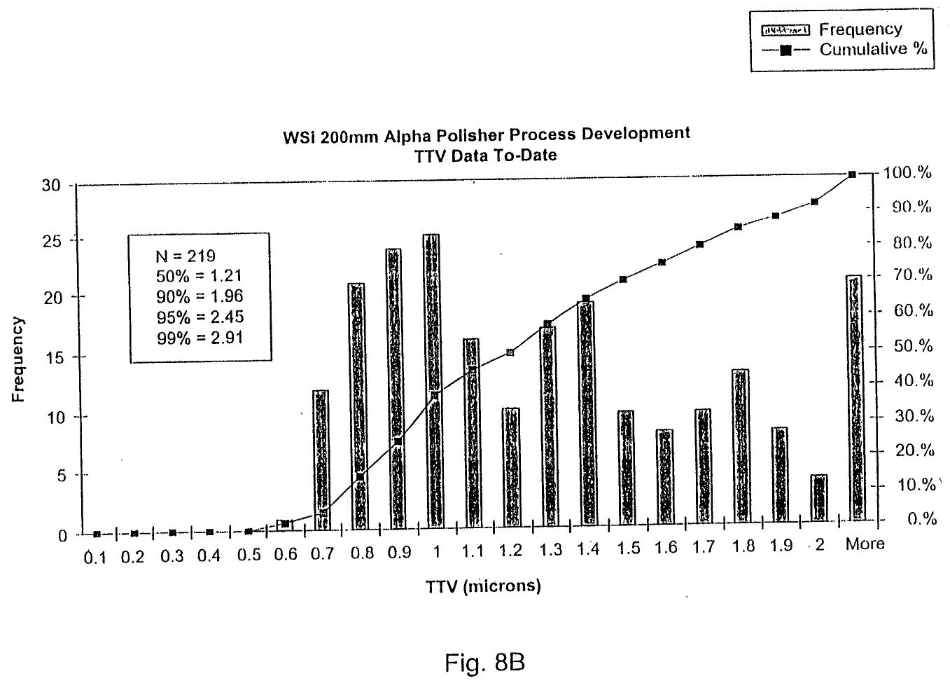

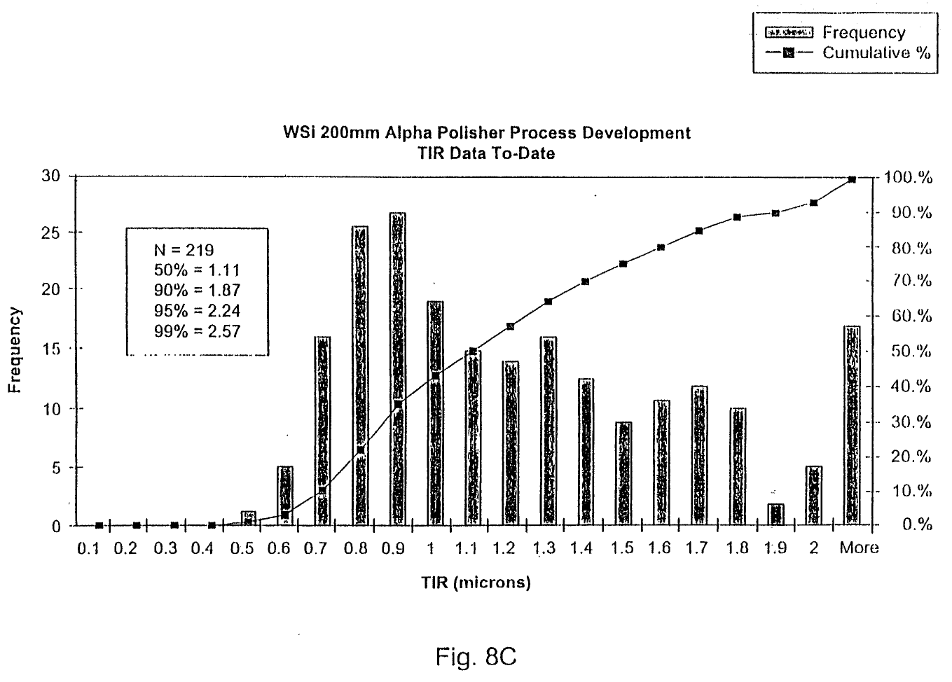

Third module 550, in one embodiment, has a compact footprint with a width 546 at the widest point of about one hundred and forty two (142) inches and a length at the longest point of about one hundred and fifty-five inches (155). Additional details of double side polishers 518 according to the present invention are discussed in conjunction with FIGS. 7A, 7B and 8A-8C.

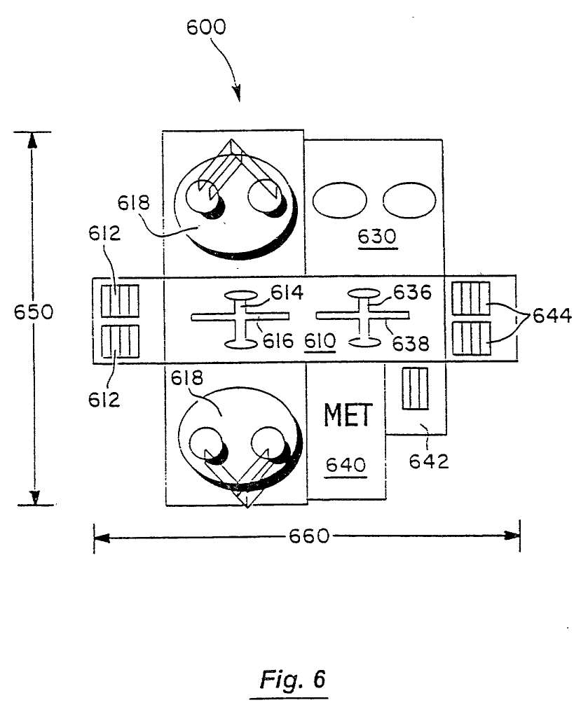

Turning now to FIG. 6, a fourth module 600, comprising a finish polish cluster, will be described. Fourth module 600 in one embodiment will be used for process step 226 shown in FIG. 2. As with the prior modules, fourth module 600 defines a clean room environment 610 which has ingress and egress through one or more portals or FOUPs. For example, an in-portal or FOUP 612 receives a plurality of wafers for finish polishing. Wafers are removed from FOUP 612 and transferred by a transfer device 614 along a track 616 to a finish polisher 618. While two finish polishers 618 are depicted in FIG. 6, a larger or smaller number of polishers 618 may be used within the scope of the present invention.

Wafers are finish polished for about five (5) to six (6) minutes within finish polisher 618 in an embodiment. Wafers that have undergone finish polishing are transferred to a single wafer cleaner 630 by a transfer device 636. Again, transfer device 636 in one embodiment comprises a robot that travels along a track 638. After wafer cleaning at cleaner station 630, wafer metrology is again tested at a metrology station 640. In one embodiment, metrology processing within fourth module 600 uses a feedback loop to provide data to finish polishers 618 as a result of wafer metrology testing. In one embodiment, the feedback loop is of sufficiently short duration to permit adjustments to the finish polisher process prior to the polishing of the next wafer after the wafer being tested. Wafers which do not meet specification are placed in a reject FOUP or portal 642 for proper disposal. Wafers meeting specifications will be placed in an out-portal or FOUP 644 for subsequent processing, packaging and shipping.

Fourth module 600, in one embodiment, has a width 650 of about 14 feet 0 inches and a length 660 of about 16 feet 0 inches. In another embodiment, fourth module 600 has a footprint ranging between about one hundred (100) square feet (sqft) and about one hundred and eighty (180) square feet. Again, as with all prior modules, the exact size may vary within the scope of the present invention. In one embodiment, fourth module 600 processes about thirty (30) wafers per hour. In another embodiment, fourth module 600 is adapted to process between about twenty-nine (29) and about thirty-three (33) 300 mm wafers per hour.

In one embodiment, the four modules 300, 400, 500 and 600, or their alternative embodiments, and ancillary equipment take up about 4,000 square feet or less of a production facility. This total footprint is much smaller than required for prior art equipment performing similar processes. As a result, apparatus, systems and methods of the present invention may be incorporated more readily in smaller facilities, or as part of a device fabrication facility in which circuit devices are formed. In this manner, the time and cost of packing and shipping, as well as unpacking and inspecting, are avoided. The costs of packing and shipping can, for example, save on the order of about two (2) percent or more of the total wafer processing costs. Additional details on exemplary in-fab wafer processing methods are discussed in U.S. patent application Ser. No. ______ (Attorney Docket No. 20468-000310), entitled “Cluster Tool Systems and Methods for In Fab Wafer Processing,” the complete disclosure of which is incorporated herein by reference.

Turning now to FIGS. 7A and 7B, exemplary double side polishing apparatus of the present invention will be described. FIG. 7A depicts a double side polishing apparatus 700, which may be double side polishing apparatus 518 depicted in FIGS. 5A and 5B. As shown in FIG. 7A, apparatus 700 includes a first plate 710 and a second plate 712. Plates 710 and 712 comprise a ceramic in one embodiment. Preferably, first plate 710 has a polishing pad 714 coupled to a surface thereof, and second plate 712 has a polishing pad 716 coupled to a surface thereof. Polishing pads 714 and 716 may comprise a wide range of pad types and materials, including pads known to those skilled in the art. In this manner, polishing pads 714 and 716 of desired textures and materials may be used within apparatus 700.

Polisher 700 further includes a carrier 718, which in one embodiment is a generally circular carrier having cutout portions of a size and shape sufficient to receive one or more wafers 720 to be polished. As shown in FIG. 7B, one embodiment of carrier 718 has three cutout portions 740 positioned about carrier 718 for receipt of three wafers 720. It will be appreciated by those skilled in the art that the number of cutouts 740 may vary within the scope of the present invention. In one embodiment, carrier 718 comprises a non-metallic material such as a plastic, polymer or the like. Carrier 718 is an improvement over metallic carriers which otherwise may damage the wafer periphery due to contact therewith.

Polisher 700 further includes a carrier ring 722 coupled to a periphery of carrier 718. In one embodiment, carrier ring 722 comprises stainless steel. The outer portion of carrier ring 722 has a plurality of teeth 760 which are adapted to engage similar teeth in a rotation device 724. Rotation device 724 rotates carrier 718, in one embodiment, by engaging carrier ring 722. Rotating carrier 718, in turn, rotates wafers 720 mounted therein. By rotating rotation device 724 about an axis 726 as indicated by arrow 728, carrier 718 is caused to be rotated about axis 770. Rotation device 724 may comprise a wide range of devices, including a gear system that engages carrier ring 722, a pulley system, a hydraulic or fluid based system, and the like.

In one embodiment, cutouts 740 within carrier 718 are slightly larger than the diameter of wafer 720. In this manner, wafers 720 rotate with the rotation of carrier 718, as well as spin within cutouts 740 as a result of contact with pads 714 and 716. In an embodiment, operation of rotation device 724 is facilitated by a controller 750 as schematically shown in FIG. 7A. Controller 750 may comprise a microprocessor and appropriate memory for operation using computer software and the like.

First plate 710 is adapted to be translated as shown by arrows 730. In one embodiment, plate 710 is translated in a back and forth manner, which is shown as a left to right motion in FIG. 7A. Similarly, second plate 712 is adapted to be translated in a generally linear or back and forth manner as shown by arrowhead 732. In one particular embodiment, the direction of translation of first plate 710 is generally perpendicular to the direction of translation of second plate 712. In one particular aspect, the translation of first and second plates are between 90° and 180° out of phase. In this manner, the translation of plates 710 and 712, coupled with the rotation of carrier 718 provide relative motion between substrates 720 and polishing pads 714 and 716, to provide exemplary double side polishing. Translation of plates 710 and 712 may be effectuated by one or more translators (not shown in FIGS. 7A and 7B). The translators may comprise a wide range of mechanical, electrical, and electro-mechanical devices that are adapted to translate plates 710 and 712 in a generally linear direction.

In one embodiment, polisher 700 further includes a gimballing device (not shown) which is coupled to at least one of plates 710, 712. The gimballing device operates to move at least one of plates 710, 712 in a manner which facilitates access to substrate 720, for example, to facilitate the insertion or removal of wafer 720 into carrier 718. Further, the gimballing device operates to maintain first and second polishing pads 714, 716 to be generally parallel. Additionally, pads 714, 716 are maintained to be generally parallel to the exposed surfaces of wafer 720 to be polished.

As shown in FIG. 7B, each wafer location 740 has a corresponding identification mark 742. In this manner, visual inspection of carrier 718 allows for the rapid identification of a desired wafer. In a particular embodiment, a wafer detection apparatus (not shown) operates to detect identification mark 742, and hence the wafer location. For example, detection device 718 may comprise a light source positioned on one side (e.g., above) carrier 718 and a light detection device positioned on the opposite side of (e.g., below) carrier 718. The detection device identifies wafer location by the unique identification mark which allows light to pass through carrier 718. While identification marks 742 are shown as holes in carrier 718, alternative identification marks and detection devices (e.g., a laser and the like) are anticipated within the scope of the present invention. In this manner, the present invention allows for the tracking and processing of single wafers using free floating polisher 700.

Further, polisher 700 has a much reduced footprint that eliminates or reduces problems associated with wafer handling, and facilitates the tracking of individual wafers for robust process control. In alternative embodiments, polisher 700 has a footprint that is less than about twenty (20) square feet, and less than about fifteen (15) square feet. In a particular embodiment, polisher 700 is about 3.5 feet per side (about 12.25 sqft). In this manner, polisher 700 is readily incorporated into the cluster tool systems of the present invention. The insertion and removal of wafer 720 in carrier 718 may be accomplished by robots, a vacuum pencil, prongs and the like. Wafer handling may comprise lifting the wafer by contacting one of the wafer surfaces, as well as by gripping the peripheral edge of wafer 720.

In a particular embodiment, at least one of the plates 710, 712 has a plurality of spaced apart holes therein. Preferably, the plurality of holes (not shown) would also pass through the polishing pad 714, 716. During polishing operations, the plurality of holes are coupled to a slurry source and distribute a polishing slurry over carrier 718 and substrates 720. After polishing has been completed, the plurality of holes in plate 710 or 712 may be flushed with deionized water or the like. In one embodiment, flushing the plate holes facilitates substrate 720 removal from carrier 718. For example, second plate 712 holes may be flushed with deionized water, forming a plurality of water jets that exit the exposed surface of polishing pad 716. The deionized water jets impinge on the adjacent surface of wafer 720, gently lifting wafer 720 at least partially out of carrier 718. Such a process exposes more of the substrate peripheral edge, thereby facilitating the removal of substrate 720 from carrier 718 by contacting only the peripheral edge. In this manner, damage to the primary surfaces of substrate 720 is reduced or eliminated.

The inventors conducted numerous tests to assess process results of the present invention. Turning now to FIGS. 8A-8C, a portion of those test results are depicted. FIG. 8A depicts the results of processing 219 wafers, and plots the substrate material removal rate in microns per minute with the number of wafers that corresponded to particular removal rates. For example, one-half of the 219 wafers had a removal rate of 1.39 microns per minute or less. Similarly, 95% of the 219 wafers had a removal rate of 2.26 microns or less per minute. FIGS. 8B and 8C depict the total thickness variation (TTV) data and the total indicated reading (TIR) data for the same 219 wafers, respectively. As seen, the total thickness variation of one-half of the wafers processed was 1.21 microns or less. Similarly, the TIR of one-half of the wafers processed was 1.11 microns, or less. Hence, as shown in FIGS. 8A-8C, exemplary polishing results were achieved using the apparatus and methods of the present invention, as described herein.

The invention has now been described in detail for purposes of clarity and understanding. However, it will be appreciated that certain changes and modifications may be practiced within the scope of the appended claims. For example, the modules may have different layouts, dimensions and footprints than as described above. Additionally, transfer devices that have been described as traveling or fixed, may also be fixed or traveling, respectively.

What is claimed is:

1. An apparatus for polishing a substrate, said apparatus comprising:
a first plate having a first polishing surface;
a second plate having a second polishing surface;
a translator for translating said first plate in a first direction and for translating said second plate in a second direction;
a carrier adapted to receive a wafer to be polished, said carrier positioned between said first plate and said second plate; and
a rotator adapted to rotate said wafer between said first and second polishing surfaces.

2. The apparatus as in claim 1 wherein said first and second polishing surfaces comprise first and second polishing pads.

3. The apparatus as in claim 1 wherein said first direction is generally perpendicular to said second direction.

4. The apparatus as in claim 1 wherein said carrier is adapted to receive at least three wafers.

5. The apparatus as in claim 1 wherein said carrier further comprises a unique identification mark positioned adjacent said wafer.

6. The apparatus as in claim 5 further comprising a detection device for reading said unique identification mark to locate a wafer position.

7. The apparatus as in claim 1 wherein said carrier comprises a non-metallic material, said carrier further having a thickness that is less than a thickness of said wafer.

8. The apparatus as in claim 1 further comprising a carrier ring coupled to a periphery of said carrier.

9. The apparatus as in claim 8 wherein said rotator is adapted to rotate said carrier by engaging said carrier ring.

10. The apparatus as in claim 1 further comprising a controller coupled to said rotator and said translator.

11. The apparatus as in claim 1 wherein said first and second plates comprise a ceramic.

12. The apparatus as in claim 1 wherein said translator comprises a first translator for translating said first plate and a second translator for translating said second plate.

13. The apparatus as in claim 4 wherein said apparatus defines a footprint that is less than about twenty (20) square feet.

14. The apparatus as in claim 1 further comprising a gimballing device to position said first and second polishing surfaces to be generally parallel to one another.

15. The apparatus as in claim 1 wherein said second plate further comprises a plurality of spaced apart holes coupled to a fluid source.

16. A method of polishing a wafer, said method comprising:
placing a wafer in a carrier, said carrier having an identification mark adjacent said wafer to identify a wafer position;
positioning said wafer between first and second polishing plates;
translating said first plate in a first direction and simultaneously translating said second plate in a second direction different than said first direction, said translating comprising a back and forth motion;
rotating said carrier to rotate said wafer relative to said first and second polishing plates;
positioning said first and second plates to contact first and second surfaces of said wafer during rotation of said carrier to polish said first and second surfaces.

17. The method of claim 16 further comprising placing at least three wafers in said carrier, said carrier having a different identification mark associated with each wafer location.

18. The method of claim 16 wherein said translating said first plate is 90 to 180 degrees out of phase with said translating said second plate.

19. The method of claim 16 wherein said first and second directions are generally perpendicular.

20. The method of claim 16 further comprising removing said wafer from said carrier after said polishing, wherein said removing comprises impinging said wafer second surface with a series of fluid jets to at least partially lift said wafer from said carrier.
